(19) United States
(12) Patent Application Publication
(10) Pub. No.: US 2010/0258858 A1
(43) Pub. Date: Oct. 14, 2010

(54) METHOD OF FABRICATING SEMICONDUCTOR DEVICE

(75) Inventor: Jung Nam Kim, Seoul (KR)

Correspondence Address: AMPACC Law Group, 3500 188th Street S.W., Suite 103, Lynnwood, WA, 98037, US

(73) Assignee: Hynix Semiconductor Inc., Icheon-si (KR)

(21) Appl. No.: 12/493,085

(22) Filed: Jun. 26, 2009

(30) Foreign Application Priority Data
Apr. 10, 2009 (KR) 10-2009-0031405

(51) Int. Cl. H01L 29/78; H01L 21/336

(52) U.S. Cl. 257/330; 438/270; 257/E21.41; 257/E29.262

(57) ABSTRACT

Provided are a structure for reducing a parasitic capacitance generated between a gate electrode and a bit line in a highly integrated semiconductor memory apparatus, and a fabrication method thereof. The method of fabricating a semiconductor device according to the invention comprises: providing a substrate including an active region and an isolation region; forming a recess over the active region and the isolation region; etching the active region and the isolating region under the recess to form a fin structure; forming a buried gate over the fin structure in a lower portion of the recess; and forming an insulating layer filling in an upper portion of the recess.

### CROSS-REFERENCE TO RELATED APPLICATION

The priority of Korean patent application No. 10-2009-0031405 filed Apr. 10, 2009, the disclosure of which is hereby incorporated in its entirety by reference, is claimed.

### BACKGROUND OF THE INVENTION

The present invention relates to a method of fabricating highly integrated semiconductor devices, and more specifically, to a fabrication method for increasing the process margin and reducing defects in a fin transistor of a highly integrated semiconductor device.

In general, semiconductor is formed of material with conductivity property corresponding to somewhere between a conductor and an insulator. At a natural state it is more like an insulator, but when impurities are added or other processes are carried out, the conductivity of a semiconductor tends to increase. Therefore, by adding impurities to a semiconductor and connecting the semiconductor to a conductor, a semiconductor element, such as, a transistor, is made, and the semiconductor element is then used to form a multifunctional device called a semiconductor device. One typical example of such semiconductor device is a semiconductor memory apparatus.

In a system configured with a plurality of semiconductor devices, the semiconductor memory apparatus serves to store data. When a data processing unit such as, for example, a central processing unit (CPU), requests data, the semiconductor memory apparatus outputs the data to a given address from the data requesting device, or stores data, which is delivered from the data requesting device, in a location corresponding to a given address.

With the increasing demands for larger data storage capacity for semiconductor memory apparatus, a number of unit cells are required to be formed in smaller size, and many components associated with read or write operation are also required to be formed in smaller size. Accordingly, wires or transistors which function same role are combined to minimize the area occupied by those components. In addition, unit cell size should be smaller for a high degree of integration.

A semiconductor memory apparatus includes a number of unit cells each of which consists of a capacitor and a transistor. Here, the capacitor is used to store data temporarily, and the transistor is used to transfer data between bit line and capacitor in response to a control signal (word line), using the nature of a semiconductor whose conductivity changes depending on environment. The transistor has three regions: gate, source and drain, and charge transfer between the source and the drain in response to a control signal received by the gate occurs in a channel region of the semiconductor substrate.

A conventional way of forming a transistor on the semiconductor substrate includes forming a gate over the semiconductor substrate and doping impurities onto both sides of the gate to form a source and a drain. In order to increase data storage capacity, a unit cell needs to be formed in a smaller size. As design rule for the capacitor and the transistor included in a unit cell becomes smaller and the channel length of a cell transistor is shorter, short channel effects, DIBL (Drain Induced Barrier Lower) effects and the like occur, thereby deteriorating operational reliability. The phenomena caused by the shortened channel length can be overcome by maintaining threshold voltage high. Conventionally, if a transistor has a shorter channel length, impurities are implanted at a higher concentration into a channel region. However, as the design rule becomes reduced to 100 nm or below, the increased doping concentration makes electric field in an SN (Storage Node) junction increased, causing another problem, i.e. deterioration of refresh characteristics of the semiconductor memory apparatus. In order to overcome this, a cell transistor having a 3D channel structure with a vertically elongated channel is used to secure long channel length of the cell transistor under smaller design rule condition.

A fin transistor is a typical example, which is used as a cell transistor having the 3D channel structure. Particularly, a fin transistor has a double gate structure, in which a channel region is formed on a silicon substrate in a protruding shape and gates are installed on both sides of the channel region. Because the vertical channel length is longer compared to a channel length in the horizontal direction, the doping may be performed at a lower concentration. Compared with the planar gate structure, the fin structure described above can significantly increase current required for driving a transistor, prevent leakage current from occurring in non-operation mode, and significantly reduce the size of the semiconductor device.

To make a fin transistor, a silicon substrate is etched to erect a silicon fin and then fill insulating film between the silicon fins. Later, the insulating film is etched to a depth suitable for forming a channel, a gate electrode is formed on the top and both sides of the exposed silicon fin, and finally source and drain regions are formed on the front and rear sides of the silicon fin, respectively. In the case where a cell transistor is formed of a fin transistor, a bit line and a capacitor are electrically connected to a drain region and a source region, respectively, through a bit line contact plug and a storage electrode contact.

Because of its excellent leakage current characteristics, a fin transistor serving as a cell transistor can increase data retention time and enhance refresh characteristics. However, as with other conventional recess gate transistors having a 3D channel structure, since a gate electrode of the fin transistor is formed at a higher level than active source or drain region, physical distance between a gate electrode and a bit line contact plug tends to be short. The short distance between the gate electrode and the bit line contact plug increases parasitic capacitance, thus impeding data flow via the bit line. In particular, the increased parasitic capacitance causes a sense amplifier receiving data from the bit line to fail in sensing the data.

### BRIEF SUMMARY OF THE INVENTION

Various embodiment of the invention are directed to providing a fabrication method that forms a fin transistor in a highly integrated semiconductor device in a buried gate structure so as to reduce parasitic capacitance between the gate electrode and the bit line and reduce resistance of the gate electrode, such that the operating margin of the a semiconductor memory apparatus can be increased.

The present invention provides a method of fabricating a semiconductor device, comprising: providing a substrate including an active region and an isolation region; forming a recess over the active region and the isolation region; etching the active region and the isolating region under the recess to form a fin structure; forming a buried gate over the fin structure in a lower portion of the recess; and forming an insulating layer filling in an upper portion of the recess.

Preferably, the metallic material includes one of tantalum and a tungsten-based metal.

Preferably, wherein the buried gate is formed from a level of about 1100 Å to about 1300 Å to a level of about 500 Å to about 650 Å.

Preferably, the insulating material includes one of a nitride film and an oxide film.

Preferably, the providing a substrate comprises: performing a shallow trench isolation process on the semiconductor substrate to form a trench; depositing an insulating material over the trench; and performing a chemical mechanical polishing process to expose the active region.

Preferably, the forming a buried gate comprises: depositing the metallic material over the fin structure; performing a chemical mechanical polishing process; and removing the metallic material deposited over the upper portion of the recess.

Preferably, the metallic material is removed through one of an etch-back process and a wet etch process.

Preferably, the method of fabricating a semiconductor device further comprises: implanting ions into the active region to form source/drain regions.

Preferably, a depth of the source/drain regions is shallower than that of the insulating layer.

Preferably, the method further comprises implanting ions into the fin structure to form a channel region; and forming a gate oxide film on the active region exposed by the recess.

Preferably, the method further comprises forming a contact over the active region; and forming a bit line over the contact.

Preferably, a depth of the recess becomes greater in the isolation region than in the active region after the active region and the isolating film under the recess are etched.

Preferably, the buried gate is formed to have a greater depth in the isolation region than in active region, and the insulating layer is formed to have substantially the same thickness in both the isolation region and active region.

Further, the present invention provides a semiconductor device, comprising: a substrate including an active region and an isolation region; a buried gate formed in a recess over the active region and the isolation region; and a fin structure positioned under the buried gate. Preferably, the buried gate is formed from a level of about 1100 Å to about 1300 Å to a level of about 500 Å to about 650 Å.

Preferably, the buried gate includes one of tantalum and a tungsten-based metal.

Preferably, the semiconductor device further comprises a channel region including the fin structure; and a gate oxide film between the buried gate and the channel region including the fin structure.

Preferably, the semiconductor device further comprises an insulating layer formed in an upper portion of the recess; and a bit line contact plug formed over the active region so as to be electrically coupled to the active region.

Preferably, the buried gate is formed to have a greater depth in the isolation region than in active region, and the insulating layer is formed to have substantially the same thickness in both the isolation region and the active region.

Preferably, the semiconductor device further comprises a source region and a drain region formed in the active region, wherein the source a depth of the source/drain regions is shallower than that of the insulating layer.

According to the present invention method of fabricating fin transistors, gate electrodes formed over the fin structure has a buried gate structure, such that the parasitic capacitance that is generated between the gate electrode and the bit line is reduced so as to facilitate the data flow via the bit line and ensure the data sensing margin of the sense amplifier.

Also, according to the present invention method, the buried gate electrodes are not made from polysilicon but from tantalum or tungsten-based (e.g., TaN or W) material, and the isolation film is further etched to make the buried gate electrodes larger in size, such that the resistance of the gate electrode is reduced and the operating speed of the semiconductor memory apparatus is increased.

### BRIEF DESCRIPTION OF THE DRAWINGS

FIG. 1 is a plan view illustrating a semiconductor memory apparatus according to an embodiment of the present invention.

FIGS. 2 to 6 are cross-sectional views illustrating a fabrication method of the semiconductor memory apparatus shown in FIG. 1.

### DESCRIPTION OF EMBODIMENTS

A cell transistor having both fin and buried gate structures is disclosed so as to improve the operating reliability and operating speed of the highly integrated semiconductor device. Hereinafter, exemplary embodiments of the invention are described in detail with reference to accompanying drawings.

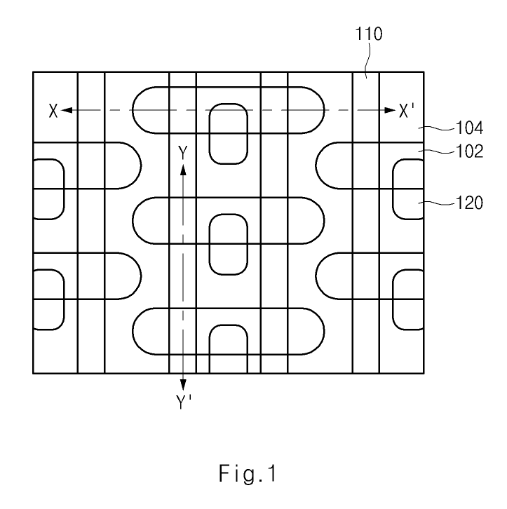

FIG. 1 is a plan view illustrating a semiconductor memory apparatus according to an embodiment of the present invention.

As shown, included in a cell region of the semiconductor memory apparatus are an active region 102 defined by an isolating film 104, a word line 110 traversing the active region 102 and a bit line contact plug 120 formed between neighboring word lines 110. Although FIG. 1 illustrates a cell region of 8F² sized unit cells, the present invention is also applicable to a different type of cell structure such as 6F² and 4F² sized unit cells. Here, ‘F’ represents a minimum distance between fine patterns under a given design rule.

Although not shown, a unit cell in the semiconductor memory apparatus according to an embodiment of the present invention includes a buried gate formed at a lower level than a source/drain region over the semiconductor substrate, and a channel region of a fin structure that is positioned below the buried gate. The following now describes the structure of a semiconductor device and its fabrication method, with reference to cross-sectional views taken along X-X′ and Y-Y′ lines shown in FIG. 1.

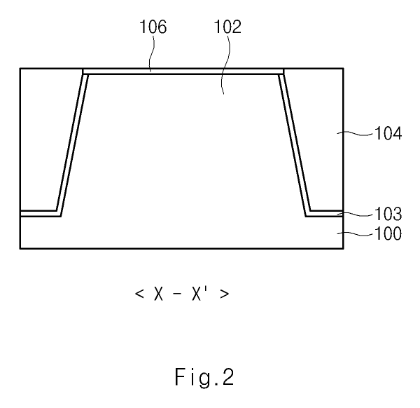

FIGS. 2 to 6 are cross-sectional views illustrating a fabrication method of the semiconductor memory apparatus shown in FIG. 1.

Referring to FIG. 2, a pad oxide film 106 is deposited over a semiconductor substrate 100, and an isolating film 104 is then formed to define an active region 102. In particular, a shallow-trench-isolation (STI) process is performed on the semiconductor substrate 100 to form a trench, and a liner nitride film 103 is then formed on the sidewalls and bottom surface of the trench. At this time, the trench is formed to a depth of about 3000 Å.

After the liner nitride film is formed, the trench is filled with an insulating material. Next, a CMP is performed until the pad oxide film 106 is exposed on the active region 102. For the insulating material to be filled in the trench, SOD (Spin-On-Dielectric) material, hard mask material, or a stack of SOD and hard mask materials can be used.

Later, although not shown, ion implantation is performed onto the active region 102 to a certain depth to form source/drain regions (not shown). In the present invention, the ion implantation onto the active region 102 is conducted before buried gate electrodes are formed. It lowers the probability of an alignment error compared with the case of conducting the ion implantation after the gate electrodes are formed, and decreases leakage current between the gate electrode and a bit line contact plug formed on the drain region or between the gate electrode and a storage electrode contact formed on the source region.

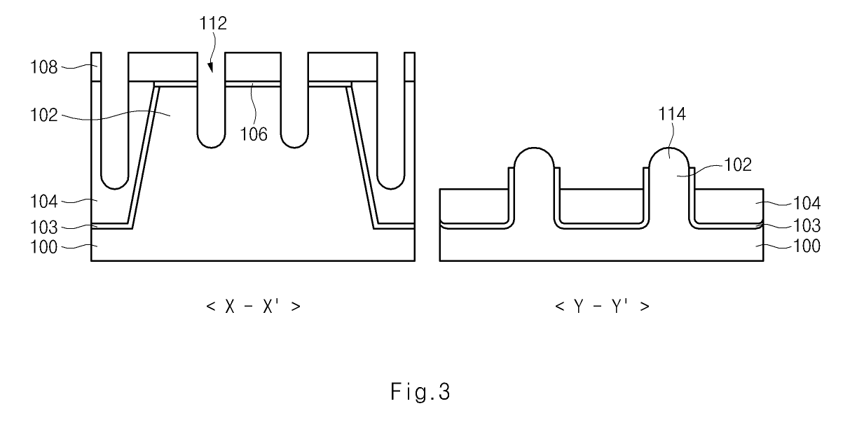

Referring to FIG. 3, a hard mask insulating film 108 is deposited over the active region 102 and the isolating film 104, and the hard mask insulating film 108 is then patterned by an etching process using a mask defining the word line 110 of FIG. 1. Next, as shown in the cross-sectional view taken along <X-X′> line, the active region 102 and the isolating film 104 are etched using the patterned hard mask insulating film to form a recess 112 in the active region 102 and the isolation film 104, to the same depth. At this time, the recesses are formed to a depth of 1100-1300 Å.

Once the etching process for forming the recess 112 is done, as shown in the cross-sectional view taken along <Y-Y′> line, the active region 102 and the isolating film 104 are further etched to make a lower portion under the recess 112 in the active region 102 have a shape of a fin structure 114. Also, the liner nitride film 103 is selectively etched to expose the top of the fin structure 114 in the active region 102. In this etching process, since the isolation film 104 having a higher etch rate than that of the nitride film or silicon substrate, the isolation film 104 is more deeply etched than the liner nitride film 103 or the silicon substrate forming the active region 102. As a result, as shown in FIG. 3, the depth of the recess 112 becomes greater in the isolation film 104 than in the active region 102.

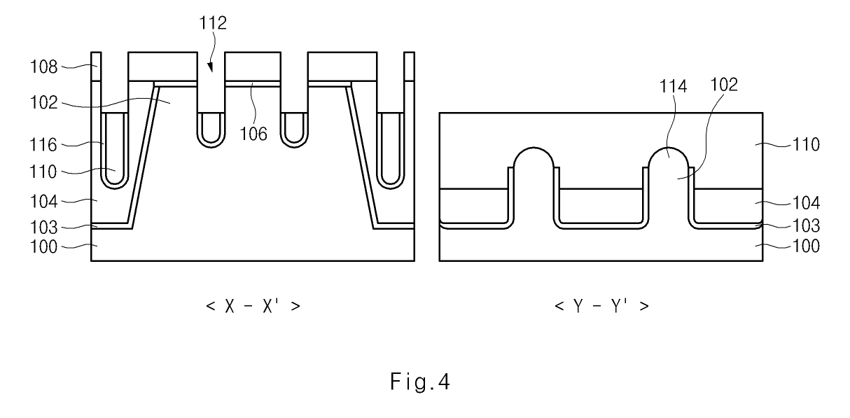

As shown in FIG. 4, a gate oxide film 116 is formed on the active region 102 exposed by the recess 112, and a metallic material is filled over the fin structure 114 formed in the recess 112 so as to form a word line 110. To reduce resistance of a gate electrode, tantalum-based or tungsten-based metallic material (TaN, W, etc.), instead of poly-silicon that was generally employed as a lower electrode for a recess gate in the art, is deposited.

An etch-back process is performed onto the gate oxide film 116 and the word line 110 so that the word line 110 is placed in a lower portion of the recess 112, with leaving empty upper portion of the recess 112 to a depth of 500-650 Å from the top. The etch depth of the metallic material formed in the first and the second recesses is determined by an offset value with respect to leakage current characteristics (GIDL etc.) and resistance characteristics (resistance at the junction, etc.), and particularly by the depth of ion implantation made in the source/drain regions formed in the active region 102. On the one hand, a wet-etching method may be employed to remove metallic materials to a certain depth in the recess 112, so as to avoid the deterioration in operating characteristics of the semiconductor device due to the remainder of metallic materials on the sidewalls of the recess 112 during the etch-back process.

Therefore, the invention can ensure a sufficient physical distance between a bit line contact plug 120 to be formed on the surface of the active region and the word line 110, by removing the metallic material at upper portion of the recess 112 and therefore forming a buried word line structure. In this way the invention can significantly reduce the parasitic capacitance generated between the word lines 110 and the bit line contact plug 120.

Also, as illustrated in FIG. 3, since the recess 112 is formed to a greater depth in the isolation film 104 than in the active region 102, the average size of cross section of the word line 110 is larger than that of a conventional buried word line. Accordingly, the overall resistance of the word line 110 connected to many unit cells can significantly be reduced.

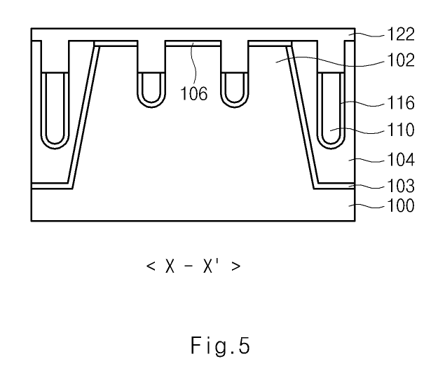

Referring to FIG. 5, a nitride film 122 made of an insulating material is deposited over the active region 102 and the isolation film 104, to fill the recess 112.

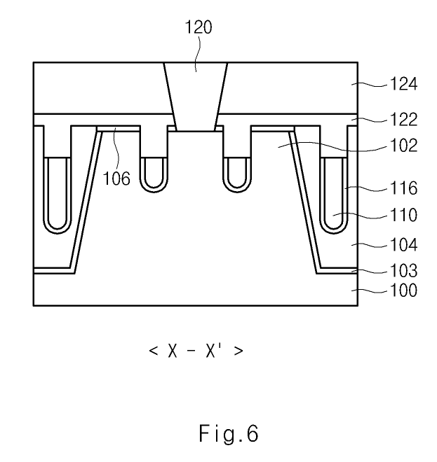

Next, referring to FIG. 6, an interlayer insulating film 124 is deposited over the nitride film 122. Later, the interlayer insulating film 124 and the nitride film 122 are etched through an etching process with a mask defining a bit line contact plug region between neighboring word lines, so as to form a contact hole exposing the active region 102. The contact hole is then filled with conductive material to form a bit line contact plug 120. A bit line (not shown) is formed to connect a plurality of the bit line contact plugs 120.

As explained above, in the fabrication method of semiconductor devices according to one exemplary embodiment of the present invention, the isolating film is formed over the semiconductor substrate to define an active region, and recesses are formed over the active region. The active region and the isolating film are additionally etched to form the fin structure, and the lower part of the recesses is filled with metallic material while the top part of the recesses is filled with an insulating material, thereby forming the buried word line structure. In this way, the semiconductor device of the invention can have characteristics of both fin transistor and buried word line structure and therefore shows excellent operating characteristics even in highly integrated semiconductors.

The exemplary embodiments of the present invention are illustrative and not limitative and those skilled in the art would appreciate that various modifications, changes, subtractions and additions are possible within the spirit and scope of the appended claims.

What is claimed is:

1. A method of fabricating a semiconductor device, comprising:
providing a substrate including an active region and an isolation region;
forming a recess over the active region and the isolation region;
etching the active region and the isolating region under the recess to form a fin structure;
forming a buried gate over the fin structure in a lower portion of the recess; and
forming an insulating layer filling in an upper portion of the recess.

2. The method of claim 1, wherein the buried gate includes one of tantalum and a tungsten-based metal.

3. The method of claim 1, wherein the buried gate is formed from a level of about 1100 Å to about 1300 Å to a level of about 500 Å to about 650 Å.

4. The method of claim 1, wherein the insulating layer includes one of a nitride film and an oxide film.

5. The method of claim 1, wherein the providing a substrate comprises:
performing a shallow trench isolation process on the semiconductor substrate to form a trench;
depositing an insulating material over the trench; and
performing a chemical mechanical polishing process to expose the active region.

6. The method of claim 1, wherein the forming a buried gate comprises:
depositing the metallic material over the fin structure;
performing a chemical mechanical polishing process; and
removing the metallic material deposited over the upper portion of the recess.

7. The method of claim 6, wherein the metallic material is removed through one of an etch-back process and a wet etch process.

8. The method of claim 1, further comprising:
implanting ions into the active region to form source/drain regions.

9. The method of claim 8, wherein a depth of the source/drain regions is shallower than that of the insulating layer.

10. The method of claim 1, further comprising:
implanting ions into the fin structure to form a channel region; and
forming a gate oxide film on the active region exposed by the recess.

11. The method of claim 1, further comprising:
forming a contact over the active region; and
forming a bit line over the contact.

12. The method of claim 1, wherein a depth of the recess becomes greater in the isolation region than in the active region after the active region and the isolating film under the recess are etched.

13. The method of claim 12, wherein the buried gate is formed to have a greater depth in the isolation region than in active region, and the insulating layer is formed to have substantially the same thickness in both the isolation region and active region.

14. A semiconductor device, comprising:
a substrate including an active region and an isolation region;
a buried gate formed in a recess over the active region and the isolation region; and
a fin structure positioned under the buried gate.

15. The semiconductor device of claim 14, wherein the buried gate is formed from a level of about 1100 Å to about 1300 Å to a level of about 500 Å to about 650 Å.

16. The semiconductor device of claim 14, wherein the metallic material includes one of tantalum and a tungsten-based metal.

17. The semiconductor device of claim 14, further comprising:
a channel region including the fin structure; and
a gate oxide film between the buried gate and the channel region including the fin structure.

18. The semiconductor device of claim 14, further comprising:
an insulating layer formed in the an upper portion of the recess; and
a bit line contact plug formed over the active region so as to be electrically coupled to the active region.

19. The semiconductor device of claim 18, wherein the buried gate is formed to have a greater depth in the isolation region than in active region, and the insulating layer is formed to have substantially the same thickness in both the isolation region and the active region.

20. The semiconductor device of claim 18, further comprising a source region and a drain region formed in the active region, wherein the source a depth of the source/drain regions is shallower than that of the insulating layer.
